(19) United States
(12) Patent Application Publication
(10) Pub. No.: US 2024/0312690 A1
(43) Pub. Date: Sep. 19, 2024

(54) EMBOSSED INDUCTOR DESIGN FOR MOTHERBOARD VOLTAGE REGULATORS TO INCREASE OVERALL SYSTEM POWER DENSITY

(71) Applicant: Intel Corporation, Santa Clara, CA (US)

(72) Inventors: Ashish SHARMA, Bangalore (IN); Arvind SUNDARAM, Bangalore (IN); Vikas MISHRA, Chandler, AZ (US); Vimal John CYRIL, Bangalore (IN)

(21) Appl. No.: 18/120,761

(22) Filed: Mar. 13, 2023

(51) Int. Cl. H01F 27/28; H01F 27/26; H05K 1/16; H05K 3/00

(52) U.S. Cl. CPC H01F 27/2804; H01F 27/266; H05K 1/165; H05K 3/005; H01F 2027/2809

(57) ABSTRACT

Embodiments disclosed herein include a motherboard. In an embodiment, the motherboard comprises a first layer with a first trace with a shape. In an embodiment, an insulating layer is provided over the first layer. In an embodiment, a second layer with a second trace with the shape is over the insulating layer. In an embodiment, the second trace is provided directly over the first trace.

### TECHNICAL FIELD

Embodiments of the present disclosure relate to electronic systems, and more particularly to motherboard voltage regulators that increase overall system power density.

### BACKGROUND

With increasing demand for higher performance of next generation central processing units (CPUs), power requirements for the CPUs increases. However, many of the data centers reuse platform and board form factors between generations in order to minimize the need for new server infrastructure. As CPU power requirements increase with a fixed system form factor, there is an utmost need to increase system power density. That is, systems need to support higher power demand within a restricted area.

Motherboard voltage regulators (MBVR) sourcing power to different CPU domains occupies significant board real estate. With increase in power demands, especially for CPU cores, a higher number of MBVR phases need to be supported from generation to generation. With each MBVR phase increment, additional power stage and output LC filters need to be added that linearly increases the board real estate. Output inductors, especially for high current rails such as VCCIN, occupy a third of the overall MBVR area on the board. Factors contributing to larger inductor sizes include equivalent series resistance (ESR) to improve quality factor, higher saturation current, and the like. For a multiphase MBVR, any reductions in real estate occupied by output inductors can significantly help increase overall system power density.

### BRIEF DESCRIPTION OF THE DRAWINGS

FIG. 1 is a plan view illustration of a board with a power delivery network that includes power stages, output inductors, and output capacitors, in accordance with an embodiment.

FIG. 2 is a plan view illustration of an output inductor that is integrated into the board, in accordance with an embodiment.

FIG. 3A is an exploded view of a board with an integrated output inductor with an S-shape, in accordance with an embodiment.

FIG. 3B is a cross-sectional illustration of the board through an end of the output inductor that shows the vias between layers, in accordance with an embodiment.

FIG. 3C is a cross-sectional illustration of the board through a middle of the output inductor that shows the spacing between the traces, in accordance with an embodiment.

FIG. 4A is an exploded view of a board with an integrated output inductor with an S-shape and magnetic blocks between layers, in accordance with an embodiment.

FIG. 4B is a cross-sectional illustration of the output inductor that illustrates the magnetic blocks between layers, in accordance with an embodiment.

FIGS. 5A-5E are cross-sectional illustrations of an insulating layer that is embossed and filled with a magnetic block, in accordance with an embodiment.

FIG. 6A is a plan view illustration of an integrated output inductor with a square loop shape, in accordance with an embodiment.

FIG. 6B is a plan view illustration of an integrated output inductor with an S-shape, in accordance with an embodiment.

FIG. 6C is a plan view illustration of an integrated output inductor with a U-shape, in accordance with an embodiment.

FIG. 6D is a plan view illustration of an integrated output inductor with a solenoid shape, in accordance with an embodiment.

FIG. 6E is a plan view illustration of an integrated output inductor with a buried S-shape, in accordance with an embodiment.

FIG. 6F is a plan view illustration of an integrated output inductor with a buried U-shape, in accordance with an embodiment.

FIG. 7 is a cross-sectional illustration of a computing system with a board that includes a motherboard voltage regulator (MBVR) that includes an integrated output inductor, in accordance with an embodiment.

FIG. 8 is a schematic of a computing device built in accordance with an embodiment.

### EMBODIMENTS OF THE PRESENT DISCLOSURE

Described herein are electronic systems, and more particularly motherboard voltage regulators that increase overall system power density, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

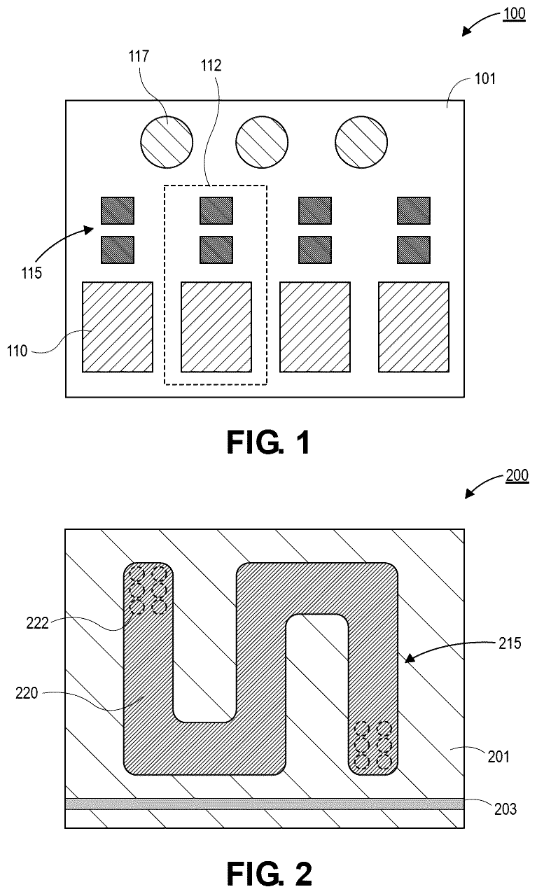

Referring now to FIG. 1, a plan view illustration of a board 100, such as a motherboard, is shown, in accordance with an embodiment. The board 100 may include a substrate 101, such as a printed circuit board (PCB). The substrate 101 may include a plurality of layers with conductive routing, insulating layers, and the like. In an embodiment, a motherboard voltage regulator (MBVR) may be provided on the substrate 101. The MBVR may comprise power stages 110, output inductors 115, and output capacitors 117. The power stages 110 and output inductors 115 may be grouped together in phases 112. For example, four phases 112 are shown in FIG. 1. That is, each phase includes one power stage 110 and one output inductor 115. The number of output capacitors 117 may be different than the number of phases 112. For example, three output capacitors 117 are shown in FIG. 1.

As noted above, increasing power demands are forcing MBVRs to increase power density. This can be done through shrinking the component sizes. However, with respect to the output inductors 115, smaller inductors result in decreases in the inductance and max saturation current limit that is not desirable for high power applications. Typically, the output inductors 115 are discrete components that are mounted on the board 100. Using discrete components for the inductors 115 leads to several challenges, such as Z-height limitations, supply chain issues, fixed discrete values available, and a reduction in the space on the top or bottom layers for signal routing.

Accordingly, embodiments disclosed herein include integrated output inductors 115. That is, the inductors 115 are integrated into the fabrication of the substrate 101. This structure provides several benefits. For example, Z-height issues are no longer problematic since the inductor is within the thickness of the substrate 101. Additionally, since the inductors 115 are fabricated as part of the substrate 101 manufacturing, there are minimal supply chain issues since discrete components no longer need to be acquired. Further, space is freed up on the top and bottom layers for signal routing.

The use of an integrated inductor 115 is also beneficial since it allows designers to more specifically control the inductance of the inductor 115 and fine tune the value to achieve optimum transient and steady state performance of MBVR. In some embodiments, the inductors 115 may be air core inductors. As used herein, an air core inductor 115 may refer to an inductor that includes an actual air core, or a core that is formed from standard board substrate materials (e.g., dielectric materials). In other embodiments, inductances can be increased by including magnetic cores within inductors 115 structure. The magnetic cores may be integrated into the inductors 115 through an embossing technique, as will be described in greater detail below.

Referring now to FIG. 2, a plan view illustration of a board 200 is shown, in accordance with an embodiment. In an embodiment, the board 200 may comprise a substrate 201. The substrate 201 may comprise laminated dielectric layers. Conductive traces 220 may be provided on the signal/conductive layers. For example, a top layer is covered by an S-shaped trace 220. Additional S-shaped traces 220 may be provided below the top layer to form an inductor 215. In an embodiment, the layers of the traces 220 may be electrically coupled together through vias 222 (shown with dashed lines to indicate they are below the trace 220). The vias 222 may be provided on a first end and a second end of the trace 220. That is, the traces 220 on different layers may be connected to each other electrically in parallel. While six vias 222 are shown on each end, it is to be appreciated that one or more vias 222 may be used based on current requirement.

In the illustrated embodiment, the shape of the trace 220 is an S-shaped trace. The S-shape provides turns that enable the formation of a desired level of inductance in the inductor 215. While an S-shape is shown in FIG. 2 as one example, it is to be appreciated that other inductor architectures may be used as well, as will be described in greater detail below. In an embodiment the shape of the trace 220 in each layer may be substantially the same. For example, the traces 220 on different layers of the substrate 201 may have the same S-shape, and each traces 220 may be positioned directly over the underlying traces 220.

In an embodiment, the traces 220 are different than the signaling traces 203. In one instance, the difference between signaling traces 203 and traces 220 may be in a width dimension. That is, a width of the traces 220 may be wider than widths of adjacent signaling traces 203. In an embodiment, the traces 220 may have a width that is up to approximately twice as large as the width of signaling traces 203, up to approximately five times as large as the width of the signaling traces 203, or up to ten times as large or larger than the width of the signaling traces 203. A thickness of the traces 220 may also be greater than a thickness of adjacent signaling traces 203.

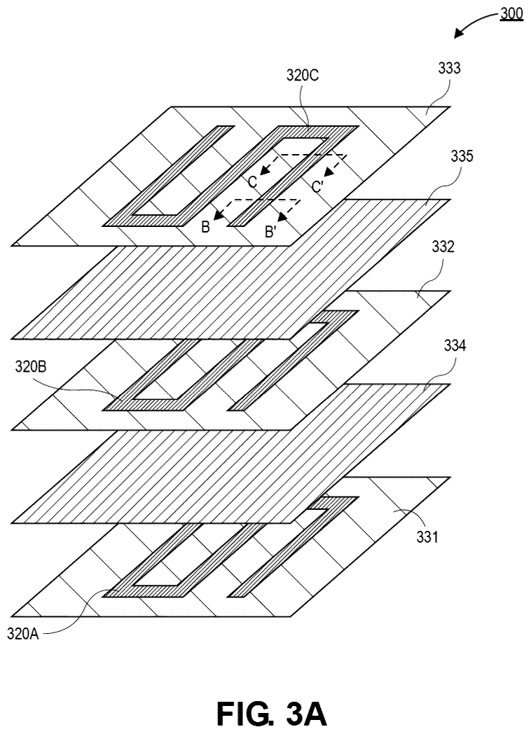

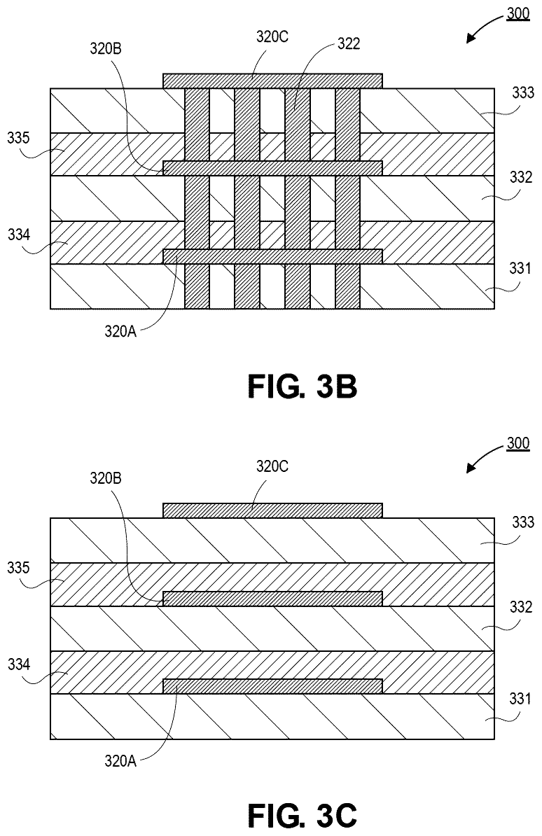

Referring now to FIG. 3A, an exploded view of a board 300 is shown, in accordance with an embodiment. The board 300 may include a plurality of layers 331-335. While five layers are shown in FIG. 3A, it is to be appreciated that the board 300 may comprise any number of layers. In an embodiment, the routing layers 331-333 may be separated from each other by insulating layers 334 and 335. The routing layers 331-333 may include traces 320A, 320B, and 320C. The traces 320A, 320B, and 320C may have the same shape and be provided directly over each other. For example, the traces 320A, 320B, and 320C have an S-shape in FIG. 3A. In an embodiment, the traces 320 may be provided over the routing layers 331-333. In other embodiments, the traces 320 may be embedded in the routing layers 331-333.

The insulating layers 334 and 335 may include any suitable insulating material, such as an organic dielectric material. The insulating layers 334 may comprise the same material as the routing layers 331-333. However, the insulating layers 334 may not include conductive traces 320. In order to electrically couple the traces 320A, 320B, and 320B together, vias (not shown) may pass through the insulating layers 334 and 335. The vias may be provided at both ends of the traces 320A, 320B, and 320C.

Referring now to FIG. 3B, a cross-section of the board 300 along line B-B′ in FIG. 3A is shown, in accordance with an embodiment. The cross-sectional illustration depicts the layers 331-335 after they have been laminated over each other. As shown, insulating layer 334 is between routing layers 331 and 332, and insulating layer 335 is between routing layers 332 and 333. In the illustrated embodiment, the traces 320A, 320B, and 320C are provided over the routing layers 331, 332, and 333, respectively. However, it is to be appreciated that the traces 320 may be embedded in the respective routing layers 331-333 in some embodiments. When the traces 320 are over the routing layers 331-333, the insulating layers 334 and 335 may conform to the shape of the traces.

In an embodiment, the cross-section of B-B′ is provided along one end of the traces 320. The end of the traces 320 may comprise a plurality of vias 322. The vias 322 may pass through the routing layers 331, 332 and 333, and through the insulating layers 334 and 335. In the illustrated embodiment, a set of four vias 322 are shown. Though, it is to be appreciated that any number of vias 322 may be used in accordance with an embodiment. In an embodiment, the vias 322 may electrically couple the traces 320 together. For example, the traces 320 may be electrically coupled to each other in parallel. That is, both a first end (shown in FIG. 3B) and a second end of the traces 320 may be electrically coupled together through vias 322.

Referring now to FIG. 3C, a cross-section of the board 300 along line C-C′ in FIG. 3A is shown, in accordance with an embodiment. As shown, the plurality of traces 320A, 320B, and 320C are spaced apart from each other by the insulating layers 334, 335 and the routing layers 332 and 333. In such an embodiment, the traces 320 may be part of an inductor that is referred to as being an air core inductor. As noted above, air core inductors include inductors with dielectric cores, such as the insulating layers 334, 335, and the routing layers 332 and 333.

As shown in FIG. 3C, the traces 320A, 320B, and 320C are directly over each other. That is, edges of the traces 320A, 320B, and 320C are substantially aligned with each other. Further, the width of the traces 320A, 320B, and 320C are substantially similar to each other. However, due to alignment tolerances in the manufacturing process, the edge of the traces 320 may be misaligned and/or the widths of the traces 320 may be non-uniform in some embodiments. That is, reference to being “substantially aligned” or “directly over” each other may include traces 320 that have at least 80% of their footprints overlapping, at least 90% of their footprints overlapping, at least 95% of their footprints overlapping, or at least 99% of their footprints overlapping.

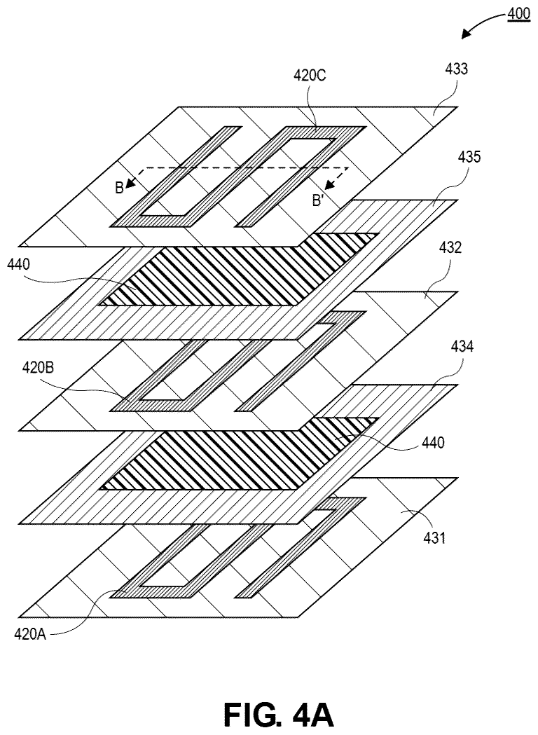

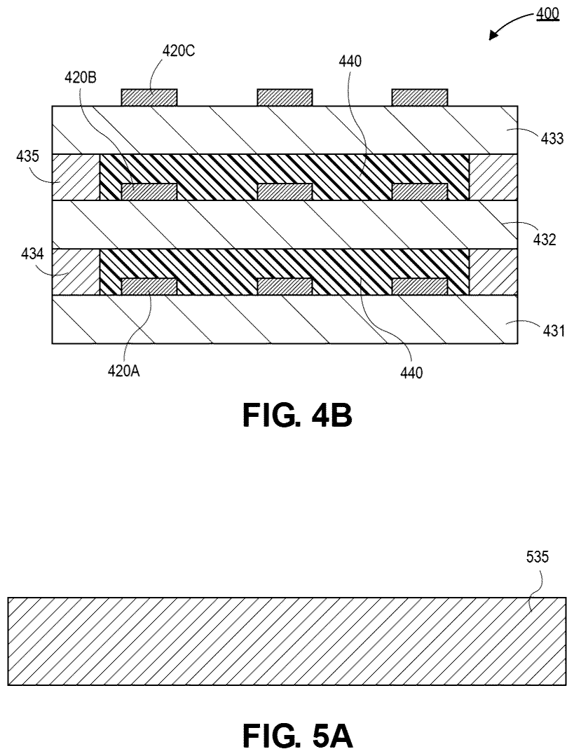

Referring now to FIG. 4A, an exploded view of a board 400 is shown, in accordance with an additional embodiment. In an embodiment, the board 400 may comprise a plurality of layers 431-435 that are stacked over each other. The layers 431-435 may include routing layers 431-433 and insulating layers 434 and 435. The routing layers 431-433 may be substantially similar to the routing layers 331-333 described above with respect to FIG. 3A. That is, the routing layers 431-433 may each comprise a trace 420A, 420B, or 420C. The traces 420 may have any suitable shape for forming an inductor, such as an S-shape or the like. The traces 420 may be on the surface of the routing layers 431-433, or the traces 420 may be embedded in the routing layers 431-433.

In an embodiment, the insulating layers 434 and 435 may be organic dielectric layers. Further, the insulating layers 434 and 435 may include cutouts that are filled with magnetic blocks 440. The magnetic blocks 440 may be any suitable magnetic material. In a particular embodiment, the magnetic blocks 440 may have a relative magnetic permeability that is approximately 200 or more at frequencies up to 1,200 KHz. For example, the magnetic blocks 440 may comprise a ferrite based material in some embodiments, such as a ferrite comprising manganese and zinc.

The magnetic blocks 440 may pass through substantially the entire thickness of the insulating layers 434 and 435. The magnetic blocks 440 may also be provided at least partially within a footprint of the traces 420A, 420B, and 420C. For example, the magnetic blocks 440 may span across three of the lengths of the traces 420. However, the magnetic blocks 440 may be within an outer perimeter of the traces 420. For example, ends of the traces 420 may be outside of the footprint of the magnetic blocks 440. This allows for the vias (not shown in FIG. 4A) to pass only through the routing layers 431-433 and the insulating layers 434 and 435. Though, in some embodiments, vias may also pass through the magnetic blocks 440.

The presence of the magnetic blocks 440 increases the inductance of the inductor in the board 400. This allows for higher power density in the MBVR in some embodiments. Further, by increasing the power density, the size of the output inductor can be decreased while maintaining the same power delivery effect. This can reduce the footprint of the MBVR in some embodiments.

Referring now to FIG. 4B, a cross-sectional illustration of the board 400 along line B-B′ in FIG. 4A is shown, in accordance with an embodiment. In an embodiment, the illustration of FIG. 4B shows the board 400 after the layers 431-435 are bonded together. As shown, the magnetic blocks 440 extend over the three lengths of each of the traces 420A, 420B, and 420C. That is, a width of the magnetic blocks 440 may be wider than a width of the traces 420A, 420B, and 420C. Though, in other embodiments, the magnetic blocks 440 may have edges that are substantially aligned with the outer edges of the traces 420A, 420B, and 420C.

In the illustrated embodiment, the magnetic blocks 440 conform to the shape of the traces 420. However, in some embodiments, the traces 420 may be embedded in the routing layers 431-433. In such instances, the magnetic blocks 440 may have top and bottom surfaces that are entirely flat, since there is no longer a need to conform to the shape of the traces 420. This may expand the group of materials that can be used for the magnetic blocks 440 since the material does not need to be a material that is soft enough to conform to an undulating surface.

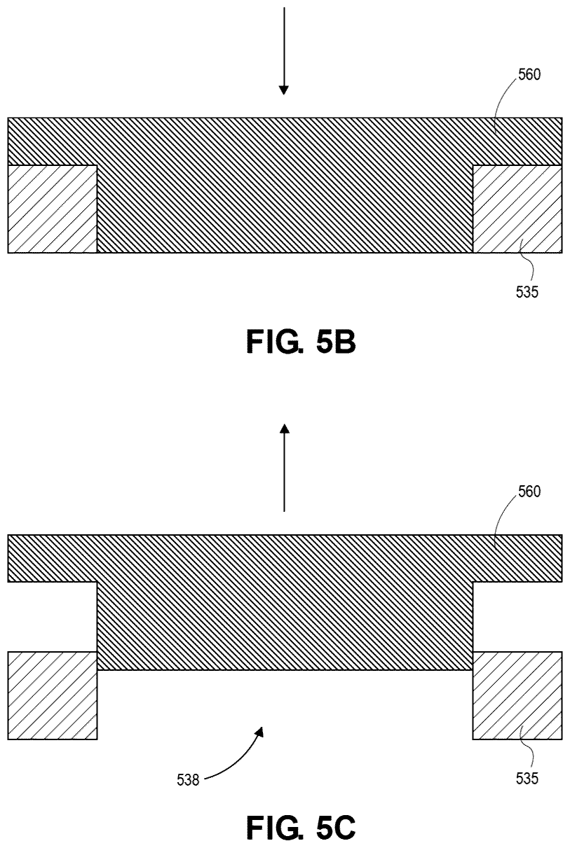

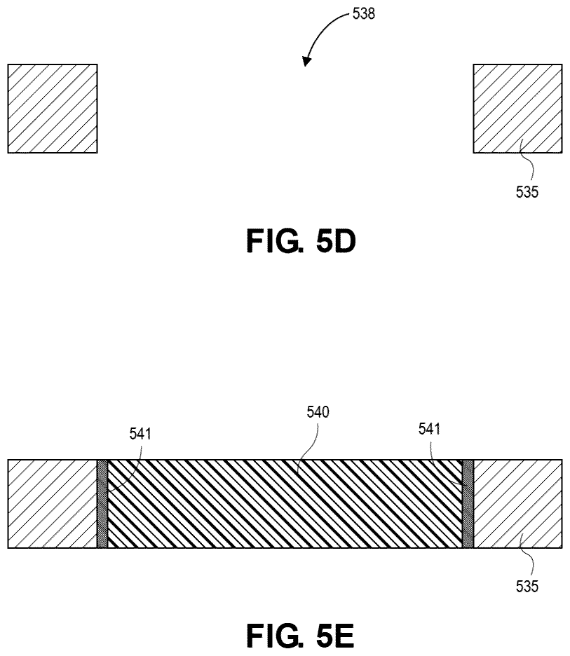

Referring now to FIGS. 5A-5E, a series of cross-sectional illustrations depicting a process for forming an insulating layer with an embedded magnetic block is shown, in accordance with an embodiment. In the particular embodiment shown in FIGS. 5A-5E, an embossing technique is used to form an opening into which the magnetic block is inserted. The magnetic block may be secured in the insulating layer with an adhesive in some embodiments.

Referring now to FIG. 5A, a cross-sectional illustration of an insulating layer 535 is shown, in accordance with an embodiment. The insulating layer 535 may comprise an organic dielectric material. For example, the insulating layer 535 may be a buildup film or the like. The insulating layer 535 may have any suitable thickness. For example, the insulating layer 535 may have a thickness up to approximately 50 μm, or up to approximately 150 μm in some embodiments. Though, thicker insulating layers 535 may also be used in some embodiments. The insulating layer 535 may be substantially free from electrically conductive features. For example, no traces may be formed on and/or in the insulating layer 535. Though, in some embodiments, one or more vias (not shown) may be provided through the insulating layer 535. In other embodiments, vias through the insulating layer 535 are formed after the formation of the magnetic block.

Referring now to FIG. 5B, a cross-sectional illustration of the insulating layer 535 during an embossing process is shown, in accordance with an embodiment. In an embodiment, a stamp 560 may be pressed into the insulating layer 535. The stamp 560 may include a protrusion that extends substantially through a thickness of the insulating layer 535. Though in some embodiments, the stamps 560 may not extend entirely through a thickness of the insulating layer 535. In such embodiments, a portion of the insulating layer 535 may remain below the protrusion. As indicated by the arrow, the stamp 560 is pressed down into the insulating layer 535. In an embodiment, the stamp 560 may be any rigid material, such as stainless steel or the like. The protrusion of the stamp 560 may have a form factor that is similar to the magnetic block that will be inserted into the insulating layer 535.

Referring now to FIG. 5C, a cross-sectional illustration of the insulating layer 535 during removal of the stamp 560 is shown, in accordance with an embodiment. As indicated by the arrow, the stamp 560 may be retracted vertically from the insulating layer 535. The removal of the stamp 560 results in the formation of an opening 538 in the insulating layer 535. The opening 538 may have substantially vertical sidewalls in some embodiments. Though, some embodiments may include an opening 538 that has sloped sidewalls in order to allow for easier removal of the stamp 560. In the particular embodiment shown in FIGS. 5A-5E, the opening 538 is formed with an embossing process. However, other fabrication processes (e.g., etching, laser ablation, etc.) may also be used in order to form the opening 538 in the insulating layer 535.

Referring now to FIG. 5D, a cross-sectional illustration of the insulating layer 535 after the opening 538 is fully formed is shown, in accordance with an embodiment. As described above, the opening 538 may have substantially vertical sidewalls, or the sidewalls may be sloped so that a bottom of the opening 538 is narrower than a top of the opening 538. While a single opening 538 is shown in the insulating layer 535, it is to be appreciated that multiple openings 538 may be provided in the insulating layer 535. Such embodiments allow for the formation of a plurality of magnetic core inductors on the same board. Each of the openings 538 may be positioned in locations where overlying and underlying traces (not shown) will be formed in order to provide the conductive loops of the inductors. Multiple magnetic core inductors enables high power density multi-phase MBVRs.

Referring now to FIG. 5E, a cross-sectional illustration of the insulating layer 535 after the insertion of a magnetic block 540 is shown, in accordance with an embodiment. In an embodiment, the magnetic block 540 may be inserted with a pick-and-place tool. That is, the magnetic block 540 may be a discrete component that is inserted into the opening 538. In an embodiment, the magnetic block 540 may be a material that has a relative magnetic permeability of 200 or greater at frequencies up to 1,200 KHz. For example the magnetic block 540 may comprise a ferrite based material.

In an embodiment, the magnetic block 540 may be secured to the insulating layer 535 by an adhesive 541. The adhesive 541 may line the sidewalls of the magnetic block 540. In some embodiments, the adhesive 541 may surround an entire perimeter of the magnetic block 540. In other embodiments, the adhesive 541 may be located at isolated locations of the magnetic block 540 (e.g., at the corners of the magnetic block 540, at midpoints of each edge of the magnetic block 540, etc.). While shown as having an adhesive 541, it is to be appreciated that an adhesive 541 is optional depending on the design of the opening 538. For example, the magnetic block 540 may be press fit into the opening 538. That is, the opening 538 may be formed slightly smaller that dimensions of the magnetic block 540, and the magnetic block 540 is pressed into the smaller opening 538.

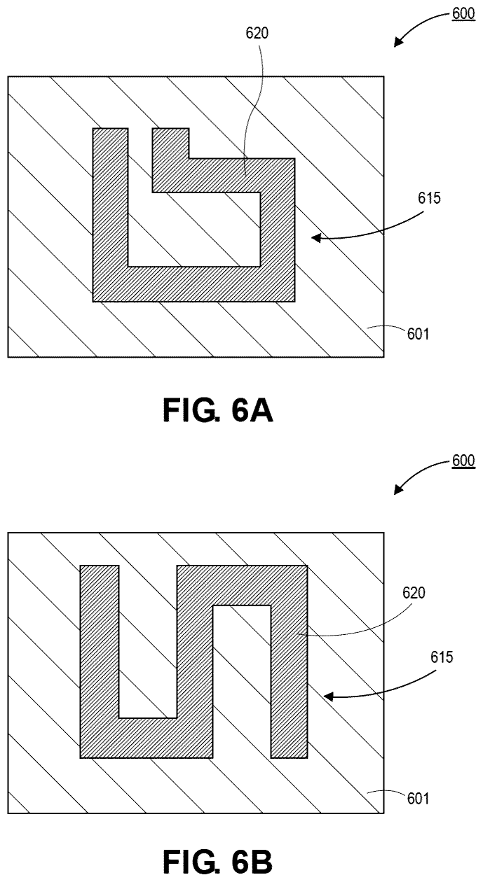

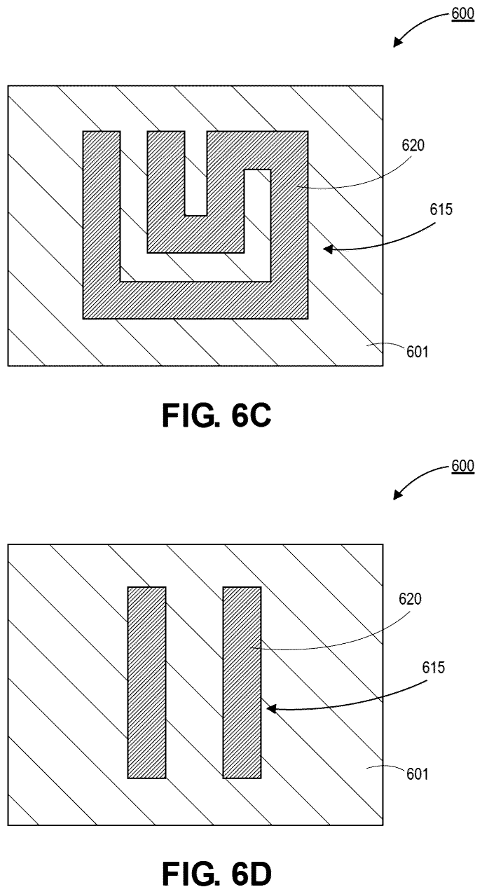

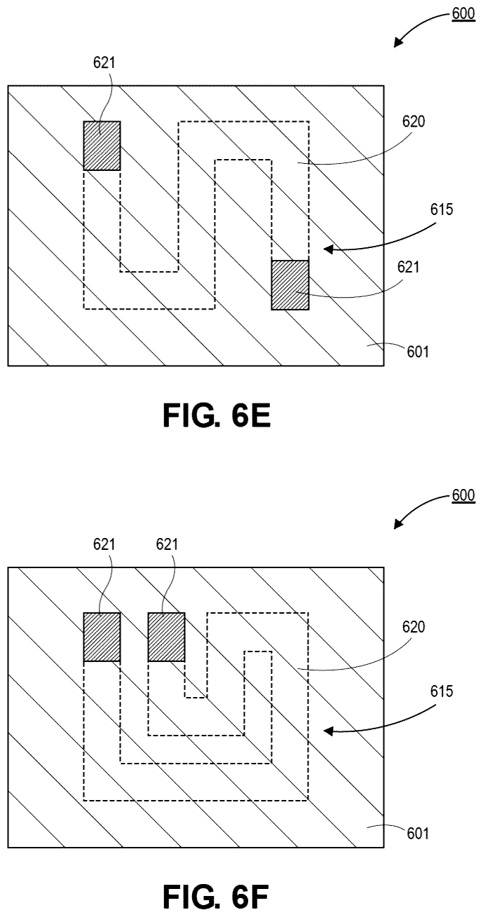

Referring now to FIGS. 6A-6F, a series of plan view illustrations of different inductor shapes are shown, in accordance with various embodiments. While particular shapes are shown, it is to be appreciated that embodiments are not limited to any specific shape. More generally, any shaped trace that can be used to form an inductive component of an MBVR can be used in accordance with embodiments described herein.

Referring now to FIG. 6A, a plan view illustration of a board 600 is shown, in accordance with an embodiment. In an embodiment, the board 600 comprises a substrate 601. The substrate 601 may comprise a plurality of layers, similar to embodiments described in greater detail above. For example, the layers may include routing layers that are separated from each other by insulating layers. In an embodiment, each of the routing layers may include a trace 620 used to form an inductor 615. In the embodiment shown in FIG. 6A, the trace 620 has a single loop configuration. The single loop of the trace 620 may be rectangular shaped, square shaped, circular, or any other shaped loop.

Referring now to FIG. 6B, a plan view illustration of a board 600 is shown, in accordance with an additional embodiment. As shown, the inductor 615 includes a trace 620 that includes a plurality of turns. For example, two turns are shown in FIG. 6B. It is to be appreciated that increasing the number of turns may allow for an increased amount of inductance. The shape of the inductor 615 shown in FIG. 6B may be referred to as having an S-shape. While the turns are formed with ninety degree angles, it is to be appreciated that the turns may include curves or non-ninety degree angles.

Referring now to FIG. 6C, a plan view illustration of a board 600 is shown, in accordance with an additional embodiment. As shown, the inductor 615 comprises a U-shaped loop. That is, the loop of the inductor does not need to be based on a circular or a standard polygonal shaped structure (e.g., triangle, rectangle, pentagon, hexagon, etc.). More complex loop shapes, such as the U-shaped loop may allow for higher inductances within a smaller area, and provides enhanced power density to the MBVR.

Referring now to FIG. 6D, a plan view illustration of a board 600 is shown in accordance with an additional embodiment. As shown, the inductor 615 comprises a solenoid type structure. That is, embodiments disclosed herein may include structures that are not traditional loop type structures.

Referring now to FIG. 6E, a plan view illustration of a board 600 is shown, in accordance with an additional embodiment. As shown, the inductor 615 comprises a pair of pads 621 on the top surface of the substrate 601. In an embodiment, the turns of the trace 620 are provided on an embedded layer of the substrate 601 (as indicated by the dashed lines). This opens up the surface of the substrate for additional routing purposes. In an embodiment, the inductor 615 shown in FIG. 6E may have an S-shape design. More particularly, each routing layer of the substrate 601 does not have to have a trace 620 with the same shape. For example, the top surface of the substrate 601 only includes pads 621.

Referring now to FIG. 6F, a plan view illustration of a board 600 is shown, in accordance with an additional embodiment. Similar to the embodiment shown in FIG. 6E, the inductor 615 includes a buried loop structure with pads 621 on the top surface. The loop shown in FIG. 6F may be U-shaped, or any other non-standard polygonal shape, such as those described in greater detail above.

In the embodiments described in greater detail above, emphasis was placed on inductor architectures that can be utilized in voltage regulator application (e.g., motherboard voltage regulator output inductors). However, embodiments are not limited to such topologies. Additionally, inductor architectures described herein can be used for many different applications. For example, noise filtering circuits on boards may utilize inductors such as those described in greater detail herein.

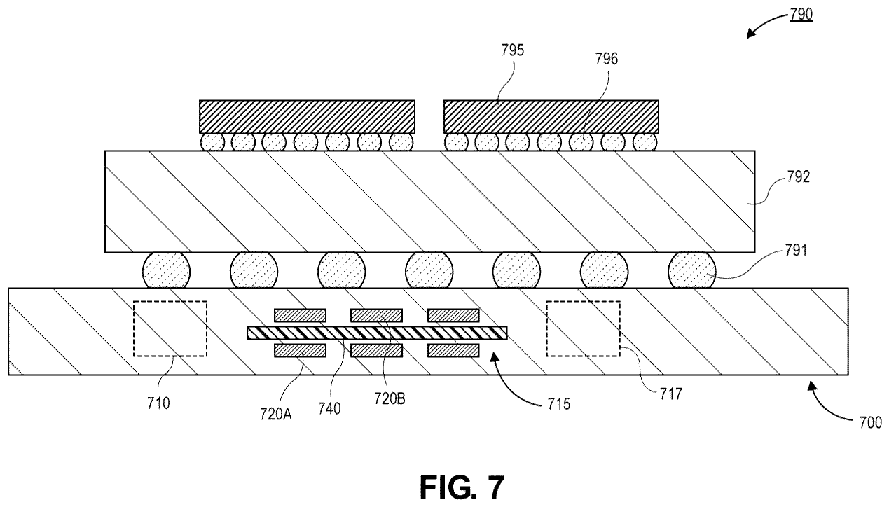

Referring now to FIG. 7, a cross-sectional illustration of a computing system 790 is shown, in accordance with an embodiment. In an embodiment, the computing system 790 may comprise a board 700. The board 700 may be similar to any of the boards described in greater detail herein. For example, the board 700 may comprise an integrated inductor 715. For example, the inductor 715 may include a first trace 720A and a second trace 720B that is positioned over the first trace 720A. The first trace 720A may be a loop with a shape, and the second trace 720B may be a loop with the same shape. The first trace 720A may be electrically coupled to the second trace 720B through vias (not shown).

In an embodiment, the first trace 720A may be separated from the second traces 720B by a magnetic block 740. The magnetic block 740 may be a ferrite based material that increases the inductance of the inductor 715. Though, an air core inductor may also be used in some embodiments.

In an embodiment, the inductor 715 may be part of an MBVR. For example, the MBVR may further comprise a power stage 710 and an output capacitor 717. The power stage 710 and the output capacitor 717 may be discrete components mounted to the board 700 and/or integrated as part of the board 700. While a single phase MBVR is shown in FIG. 7, it is to be appreciated that multi-phase MBVRs may be formed with substantially similar processes and architectures.

In an embodiment, the board 700 may be coupled to a package substrate 792 by interconnects 791. The interconnects 791 may comprise solder bumps, sockets, or the like. In an embodiment, the board 700 may comprise dielectric buildup layers (e.g., buildup film) with (or without) a core. The core may be an organic core, a glass core, or the like.

In an embodiment, the package substrate 792 may be coupled to one or more dies 795 by interconnects 796. The interconnects 796 may be solder bumps, copper bumps, or any other suitable first level interconnect (FLI). In some embodiments, an interposer or the like (not shown) may be provided between the package substrate 792 and the dies 795. The one or more dies 795 may comprise compute dies, such as a central processing unit (CPU), a graphics processing unit (GPU), an XPU, a system on a chip (SoC), a communications die, or the like. One or more dies 795 may also be memory dies or the like.

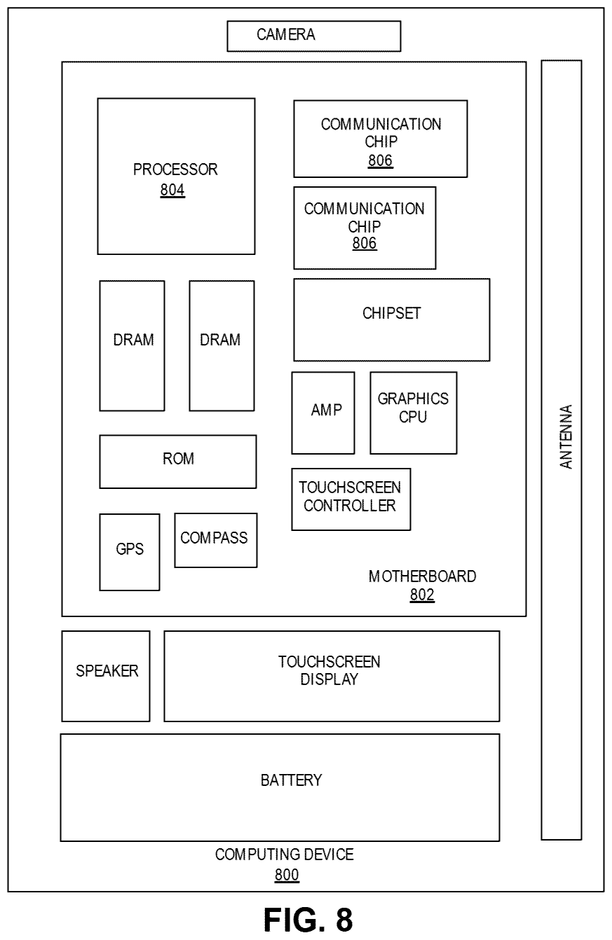

FIG. 8 illustrates a computing device 800 in accordance with one implementation of the invention. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the invention, the integrated circuit die of the processor may be part of an electronic package with a motherboard that includes an MBVR that comprises an integrated output inductor that is an air core inductor or a magnetic core inductor, in accordance with embodiments described herein. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the invention, the integrated circuit die of the communication chip may be part of an electronic package with a motherboard that includes an MBVR that comprises an integrated output inductor that is an air core inductor or a magnetic core inductor, in accordance with embodiments described herein.

In an embodiment, the computing device 800 may be part of any apparatus. For example, the computing device may be part of a personal computer, a server, a mobile device, a tablet, an automobile, or the like. That is, the computing device 800 is not limited to being used for any particular type of system, and the computing device 800 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a motherboard, comprising: a first layer with a first trace with a shape; a layer comprising insulating material over the first layer; and a second layer with a second trace with the shape over the insulating layer, wherein the second trace is provided directly over the first trace, and wherein the first trace is electrically coupled to the second trace by one or more vias through the layer.

Example 2: the motherboard of Example 1, wherein the one or more vias are at a first end of the shape and/or a second end of the shape.

Example 3: the motherboard of Examples 1-2, further comprising: a magnetic block embedded in the insulating layer between the first trace and the second trace.

Example 4: the motherboard of Example 3, wherein the magnetic block is secured to the insulating layer by an adhesive or, wherein the magnetic block is press fitted to the insulating layer.

Example 5: the motherboard of Examples 1-4, wherein the first trace and the second trace form an inductor that is integrated into the motherboard.

Example 6: the motherboard of Example 5, wherein the inductor is part of a voltage regulator or part of a noise filtering circuit.

Example 7: the motherboard of Examples 1-6, wherein the shape is an S-shape.

Example 8: the motherboard of Examples 1-6, wherein the shape is a U-shape.

Example 9: the motherboard of Examples 1-8, further comprising: a second insulator over the second layer; and a third layer with a third trace with the shape over the second insulating layer, wherein the third trace is provided directly over the first trace and the second trace.

Example 10: the motherboard of Examples 1-9, wherein the first trace and the second trace have a first width, and wherein an adjacent third trace has a second width, wherein the first width is greater than the second width.

Example 11: a motherboard, comprising: a voltage regulator, wherein the voltage regulator comprises: a power stage; an output inductor, wherein the output inductor is integrated into the motherboard, wherein being integrated into the motherboard comprises one or more conductive layers that are embedded within layers of the motherboard; and an output capacitor.

Example 12: the motherboard of Example 11, wherein a number of power stages is equal to a number of output inductors to provide a multi-phase voltage regulator.

Example 13: the motherboard of Example 11 or Example 12, wherein the output inductor comprises a first trace with a shape and a second trace with the shape directly over the first trace.

Example 14: the motherboard of Example 13, wherein the first trace is electrically coupled to the second trace in parallel.

Example 15: the motherboard of Example 13 or Example 14, further comprising: a magnetic block between the first trace and the second trace.

Example 16: the motherboard of Example 15, wherein the magnetic block comprises manganese and zinc.

Example 17: the motherboard of Examples 13-16, wherein the shape is an S-shape or a U-shape.

Example 18: a computing system, comprising: a board with a voltage regulator or noise filtering circuit that comprises an output inductor with a first trace, a second trace, and a magnetic block between the first trace and the second trace; a package substrate coupled to the board; and a die coupled to the package substrate.

Example 19: the computing system of Example 18, wherein the second trace is over the first trace, and wherein the first trace is electrically coupled to the second trace in parallel.

Example 20: the computing system of Example 18 or Example 19, wherein the computing system is part of a personal computer, a server, a mobile device, a tablet, or an automobile.

What is claimed is:

1. A motherboard, comprising:
a first layer with a first trace with a shape;
a layer comprising insulating material over the first layer; and
a second layer with a second trace with the shape over the layer, wherein the second trace is provided directly over the first trace, and wherein the first trace is electrically coupled to the second trace by one or more vias through the layer.

2. The motherboard of claim 1, wherein the one or more vias are at a first end of the shape and/or a second end of the shape.

3. The motherboard of claim 1, further comprising:
a magnetic block embedded in the insulating layer between the first trace and the second trace.

4. The motherboard of claim 4, wherein the magnetic block is secured to the insulating layer by an adhesive or, wherein the magnetic block is press fitted to the insulating layer.

5. The motherboard of claim 1, wherein the first trace and the second trace form an inductor that is integrated into the motherboard.

6. The motherboard of claim 5, wherein the inductor is part of a voltage regulator or part of a noise filtering circuit.

7. The motherboard of claim 1, wherein the shape is an S-shape.

8. The motherboard of claim 1, wherein the shape is a U-shape.

9. The motherboard of claim 1, further comprising:
a second insulator over the second layer; and
a third layer with a third trace with the shape over the second insulating layer, wherein the third trace is provided directly over the first trace and the second trace.

10. The motherboard of claim 1, wherein the first trace and the second trace have a first width, and wherein an adjacent third trace has a second width, wherein the first width is greater than the second width.

11. A motherboard, comprising:
a voltage regulator, wherein the voltage regulator comprises:
a power stage;
an output inductor, wherein the output inductor is integrated into the motherboard, wherein being integrated into the motherboard comprises one or more conductive layers that are embedded within layers of the motherboard; and
an output capacitor.

12. The motherboard of claim 11, wherein a number of power stages is equal to a number of output inductors to provide a multi-phase voltage regulator.

13. The motherboard of claim 11, wherein the output inductor comprises a first trace with a shape and a second trace with the shape directly over the first trace.

14. The motherboard of claim 13, wherein the first trace is electrically coupled to the second trace in parallel.

15. The motherboard of claim 13, further comprising:
a magnetic block between the first trace and the second trace.

16. The motherboard of claim 15, wherein the magnetic block comprises manganese and zinc.

17. The motherboard of claim 13, wherein the shape is an S-shape or a U-shape.

18. A computing system, comprising:
a board with a voltage regulator or noise filtering circuit that comprises an output inductor with a first trace, a second trace, and a magnetic block between the first trace and the second trace;
a package substrate coupled to the board; and
a die coupled to the package substrate.

19. The computing system of claim 18, wherein the second trace is over the first trace, and wherein the first trace is electrically coupled to the second trace in parallel.

20. The computing system of claim 18, wherein the computing system is part of a personal computer, a server, a mobile device, a tablet, or an automobile.
